(19) United States
(12) Patent Application Publication
(10) Pub. No.: US 2024/0113235 A1
(43) Pub. Date: Apr. 4, 2024

(54) SILICON CARBIDE DEVICE WITH SINGLE METALLIZATION PROCESS FOR OHMIC AND SCHOTTKY CONTACTS

(71) Applicant: Wolfspeed, Inc., Durham, NC (US)

(72) Inventor: Rahul R. Potera, Apex, NC (US)

(21) Appl. No.: 17/957,737

(22) Filed: Sep. 30, 2022

(51) Int. Cl. H01L 29/872; H01L 21/266; H01L 21/324; H01L 29/06; H01L 29/16

(52) U.S. Cl. CPC H01L 29/872; H01L 21/266; H01L 21/3245; H01L 29/0619; H01L 29/1608

(57) ABSTRACT

A semiconductor device includes a semiconductor layer having an active region and an edge termination region, and first metal regions on the semiconductor layer in the active region of the semiconductor layer. The first metal regions include a first metal. The device further includes second metal regions on the semiconductor layer in the edge termination region of the semiconductor layer. The second metal regions include the first metal. The device includes a first metal layer on the semiconductor layer in the active region of the semiconductor layer. The first metal layer includes a second metal, and the metal layer contacts the first metal regions and contacts the semiconductor layer in spaces between the first metal regions.

### BACKGROUND

The present disclosure relates to semiconductor device structures and in particular to silicon carbide semiconductor devices including both ohmic and Schottky contacts.

Narrow bandgap semiconductor materials, such as silicon (Si) and gallium arsenide (GaAs), are widely used in semiconductor devices for low power and, in the case of Si, low frequency applications. However, these semiconductor materials may not be well-suited for high power and/or high frequency applications, for example, due to their relatively small bandgaps (1.12 eV for Si and 1.42 for GaAs at room temperature) and relatively small breakdown voltages.

Interest in high power, high temperature and/or high frequency applications and devices has focused on wide bandgap semiconductor materials such as silicon carbide (3.2 eV for 4H—SiC at room temperature) and the Group III nitrides (e.g., 3.36 eV for GaN at room temperature). These materials may have higher electric field breakdown strengths and higher electron saturation velocities than GaAs and Si.

One important application for wide bandgap semiconductors such as silicon carbide is in Schottky diodes.

A Schottky diode, also known as Schottky barrier diode, is a semiconductor diode formed by the junction of a semiconductor with a metal. The metal-semiconductor junction (instead of a semiconductor-semiconductor junction as in conventional PN-junction diodes) in a Schottky diode creates a Schottky barrier. The metal side acts as the anode, and an n-type semiconductor acts as the cathode of the diode. When sufficient forward voltage is applied to overcome the Schottky barrier of the metal-semiconductor junction, current flows through the device in the forward direction. When a reverse voltage is applied, a depletion region is formed in the semiconductor, obstructing current flow.

Compared to a conventional PN-junction diode, a Schottky diode has a low forward voltage drop and a very fast switching action.

An important difference between a PN-junction diode and a Schottky diode is the reverse recovery time (tᵣᵣ), which it the time it takes of the diode to switch from a conducting (forward biased) state to a non-conducting (reverse biased) state. In the conducting state, a conventional PN-junction diode injects minority carriers into the diffusion region on the N-side of the junction where they recombine with majority carriers after diffusion. The reverse recovery time of a PN-junction is primarily limited by the diffusion capacitance of minority carriers accumulated in the diffusion region during the conducting state.

In contrast, a Schottky diode is a unipolar or “majority carrier” device that does not rely on minority carrier injection. Rather, in the conducting state, majority carriers (electrons in the case of an n-type semiconductor layer) are injected across the junction. Thus, switching a Schottky diode from a conducting to a non-conducting state does not require time for recombination of the injected carriers. Rather, the switching speed of a Schottky diode is only limited by the junction capacitance of the device.

Silicon carbide Schottky diodes are the rectifiers of choice in advanced power electronics at 650V and above, primarily because they achieve fast switching speeds with much lower leakage current and capacitance than silicon-based Schottky diodes.

### SUMMARY

A method of manufacturing a semiconductor device according to some embodiments includes forming first metal regions on a semiconductor layer in a first region of the semiconductor layer. The first metal regions include a first metal. The method includes forming second metal regions on the semiconductor layer in a second region of the semiconductor layer. The second metal regions include the first metal. The semiconductor layer including the first and second metal regions is annealed at a first anneal temperature to convert at least portions of the first metal regions and the second metal regions into first metal silicide regions and second metal silicide regions, respectively. The semiconductor layer including the first and second metal silicide regions is annealed at a second anneal temperature to cause the first metal silicide regions to form a Schottky barrier junction to the semiconductor layer. A first metal layer is formed on the semiconductor layer in the first region of the semiconductor layer. The first metal layer includes a second metal, and the metal layer contacts the first metal regions and contacts the semiconductor layer in spaces between the first metal regions.

The first metal may include nickel, titanium, molybdenum and/or tungsten, and wherein second metal includes titanium or titanium nitride.

The semiconductor layer includes silicon. In some embodiments, the semiconductor layer includes silicon carbide.

The first metal regions and the second metal regions may be formed simultaneously.

The method may further include removing un-silicided portions of the first metal regions and the second metal regions after annealing the semiconductor layer to form the first and second metal silicide regions.

The first metal silicide regions may form a first Schottky barrier junction to the semiconductor layer and the metal layer to may form a second Schottky barrier junction to the semiconductor layer. The first Schottky barrier junction has a first Schottky barrier height and the second Schottky barrier junction has a second Schottky barrier height that is lower than the first Schottky barrier height.

The first Schottky barrier height may be at least about 0.5 eV greater than the second Schottky barrier height. In some embodiments, the first Schottky barrier height may be about 1.6 eV or greater and the second Schottky barrier height is about 1.2 eV or lower.

The first region of the semiconductor layer may correspond to an active region of the semiconductor device and the second region of the semiconductor layer may correspond to an edge termination region of the semiconductor device.

In some embodiments, the first anneal temperature is from about 600° C. to about 700° C.

The semiconductor layer may include a substrate and an epitaxial layer on the substrate. The method may further include forming a second metal layer on a backside of the substrate opposite the epitaxial layer, wherein the second metal layer includes the first metal.

Annealing the semiconductor layer at the second anneal temperature may include annealing the semiconductor layer including the first metal regions and the second metal layer at the second anneal temperature. The second anneal temperature may be sufficient for the first metal regions to form a Schottky barrier contact to the semiconductor layer and for the second metal layer to form an ohmic contact to the doped region of the semiconductor layer. The second anneal temperature may be from about 850° C. to about 900° C.

The semiconductor layer may be an epitaxial semiconductor layer on a front surface of a semiconductor substrate, and the second metal layer may be formed on the epitaxial semiconductor layer.

The method may further include forming a first plurality of trenches in the first region of the semiconductor layer, wherein the first metal regions are formed in the first plurality of trenches.

The method may further include forming a second plurality of trenches in the second region of the semiconductor layer, wherein the second metal regions are formed in the second plurality of trenches.

The method may further include forming a plurality of trenches in the second region of the semiconductor layer, wherein the second metal regions are formed in the plurality of trenches.

Forming the first metal regions and the second metal regions on the semiconductor layer may include forming a mask on the semiconductor layer, forming openings in the mask in the first region and the second region of the semiconductor layer to expose respective areas of the semiconductor layer, and depositing a preliminary layer of the first metal on the semiconductor layer. The preliminary layer of the first metal contacts the semiconductor layer in the exposed areas of the semiconductor layer, and annealing the semiconductor layer causes portions of the preliminary layer of the first metal contacting the semiconductor layer to become silicided. The method may further include, after annealing the semiconductor layer, stripping the mask and un-silicided portions of the preliminary layer of the first metal from the semiconductor layer.

A semiconductor device according to some embodiments includes a semiconductor layer having an active region and an edge termination region, and first metal regions on the semiconductor layer in the active region of the semiconductor layer, wherein the first metal regions include a first metal. The device further includes second metal regions on the semiconductor layer in the edge termination region of the semiconductor layer, wherein the second metal regions include the first metal, and a first metal layer on the semiconductor layer in the active region of the semiconductor layer. The first metal layer includes a second metal. The first metal layer contacts the first metal regions and contacts the semiconductor layer in spaces between the first metal regions.

The first metal may include nickel, titanium, molybdenum and/or tungsten, and wherein second metal includes titanium or titanium nitride.

The semiconductor layer includes silicon. In some embodiments, the semiconductor layer includes silicon carbide.

The first metal regions include first metal silicide regions and the second metal regions include second metal silicide regions.

The first metal silicide regions may form a first Schottky barrier junction to the semiconductor layer in the first region of the semiconductor layer, wherein the first Schottky barrier junction has a first Schottky barrier height, and the first metal layer may form a second Schottky barrier junction to the semiconductor layer. The second Schottky barrier junction has a second Schottky barrier height that is lower than the first Schottky barrier height.

The first Schottky barrier height is at least about 0.5 eV greater than the second Schottky barrier height. In some embodiments, the first Schottky barrier height is about 1.6 eV or greater and the second Schottky barrier height is about 1.2 eV or lower.

The semiconductor layer may include an epitaxial layer on a substrate, and the semiconductor device may further include a second metal layer on a back side of the substrate opposite the epitaxial layer, wherein the second metal layer includes the first metal and forms an ohmic contact to the substrate.

The semiconductor device may further include a first plurality of trenches in the active region of the semiconductor layer, wherein the first metal regions are in the first plurality of trenches.

The semiconductor device may further include a second plurality of trenches in the edge termination region of the semiconductor layer, wherein the second metal regions are in the second plurality of trenches.

The semiconductor device may further include a plurality of trenches in the edge termination region of the semiconductor layer, wherein the second metal regions are in the plurality of trenches.

### BRIEF DESCRIPTION OF THE DRAWINGS

FIG. 1 illustrates a Schottky diode according to some embodiments.

FIGS. 2A to 2H illustrate operations for forming a Schottky diode in accordance with some embodiments.

FIGS. 3A to 3G illustrate operations for forming a Schottky diode in accordance with further embodiments.

FIG. 4 is a flowchart illustrating operations according to some embodiments.

FIG. 5 illustrates a Schottky diode structure according to further embodiments.

FIGS. 6A to 6D illustrated operations for forming a Schottky diode according to further embodiments.

### DETAILED DESCRIPTION OF EMBODIMENTS

Embodiments of the inventive concepts will now be described in connection with the accompanying drawings.

SiC Schottky diodes have begun finding use in price-sensitive applications, where it is very important to reduce the cost of the device even at the expense of certain performance specifications. Cost can be reduced not only by shrinking the die, but also by reducing the number of fabrication steps and, in particular, eliminating expensive steps such as high temperature ion implantation and implant annealing.

Some embodiments provide methods of forming SiC-based Schottky diodes using the same metallization process to form both a Schottky contact and one or more other contacts to the device, such as an ohmic contact, which may simplify the fabrication process.

Although methods and devices according to some embodiments may impair some properties of the device, such as blocking voltage or surge current performance, that may be an acceptable tradeoff depending on the desired application.

Some embodiments may reduce the number of required mask moves by up to 40% (e.g. 3 vs 5 for a previous approach) and/or may eliminate certain expensive fabrication steps, such as ion implantation, implant activation, wafer thinning, and/or laser anneal steps.

In some embodiments, the same metallization process may be used to form anode and cathode contacts. In some embodiments, the same metallization process may also be used to form floating equipotential rings in the termination region of the diode.

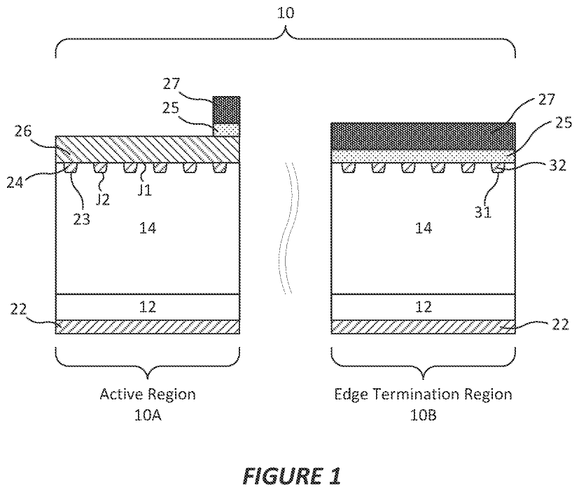

A Schottky diode 10 according to some embodiments is illustrated in FIG. 1. The Schottky diode 10 includes an active region 10A and an edge termination region 10B (also called a junction termination region, or simply a termination region). Although the active region 10A and the edge termination region 10B are shown in FIG. 1 as separate regions for ease of illustration, it will be appreciated that they are part of the same device.

An n-silicon carbide epitaxial layer 14 is formed on a silicon carbide substrate 12. A metal Schottky contact 26 is formed on the surface of the silicon carbide epitaxial layer 14 opposite the substrate 12. The Schottky contact 26 forms a first Schottky barrier junction J1 with the silicon carbide epitaxial layer 14.

At the surface of the silicon carbide epitaxial layer 14, a plurality of metal shielding regions 24 are provided within rounded trenches 23 formed at the surface of the silicon carbide epitaxial layer 14. The metal shielding regions 24 form a second Schottky barrier junction J2 with the silicon carbide epitaxial layer 14.

The first Schottky barrier junction J1 between the Schottky contact 26 and the silicon carbide epitaxial layer 14 has a lower Schottky barrier energy than the second Schottky barrier junction J2 between the metal shielding regions 24 and the silicon carbide epitaxial layer. This allows the first Schottky barrier junction J1 to turn on before the second Schottky barrier junction J2 in the forward biased (conducting) state. Conversely, in the reverse biased (non-conducting) state, the first Schottky barrier junction J1 is shielded from high electric fields by the depletion region formed at the interface of the second Schottky barrier junction J2 and the silicon carbide epitaxial layer 14.

A cathode ohmic contact 22 is formed on the back side of the substrate 12.

In the edge termination region 10B, a plurality of floating equipotential rings 32 (also called guard rings or field rings) are formed in respective trenches 31 at the surface of the silicon carbide epitaxial layer 14. A silicon nitride passivation layer 25 is formed over the edge termination region 10B and extends onto the Schottky contact 26 in the active region 10A. A protective layer 27 of a material such as polyimide is formed on the silicon nitride passivation layer 25.

According to some embodiments, the higher barrier metal in the metal shielding regions 24 shields the Schottky contact 26, which is formed by a barrier metal that forms a lower Schottky junction barrier height than the metal shielding regions 24. In some embodiments, the metal in the metal shielding regions 24 may be nickel silicide (NiSi), while the metal in the Schottky contact 26 may be a metal such as titanium or titanium nitride. In particular, the metal of the metal shielding regions 24 may have a Schottky barrier height that is at least 0.5 eV greater than the metal to form the Schottky contact 26. Because of this difference in Schottky barrier height, the leakage current of the device is determined by the barrier formed by the Schottky contact 26, even though the metal shielding regions 24 in the trenches 23 is exposed to a higher electric field.

Some embodiments use oxide patterns to define regions where silicidation is blocked, thereby simultaneously forming the metal shielding regions in the active region 10A and the equipotential rings 32 in the termination region 10B of the diode 10.

Because some embodiments do not use implanted regions to form junction barrier Schottky (JBS) regions in the silicon carbide epitaxial layer 14, no high temperature implantation and/or implant activation steps may be needed to form the SiC diode structure 10.

In some embodiments, a single metallization process may be used to form the cathode ohmic contact 22 to the back side of the substrate 12 and the metal shielding regions 24 in the active region, as well as the floating equipotential rings 32 in the termination region 10B. Moreover, in some cases, backside thinning and laser annealing to form the cathode ohmic contact 22 may be avoided. Thinning and laser annealing can cause wafer breakage, especially when working with large diameter (e.g., 200 mm or greater) wafers.

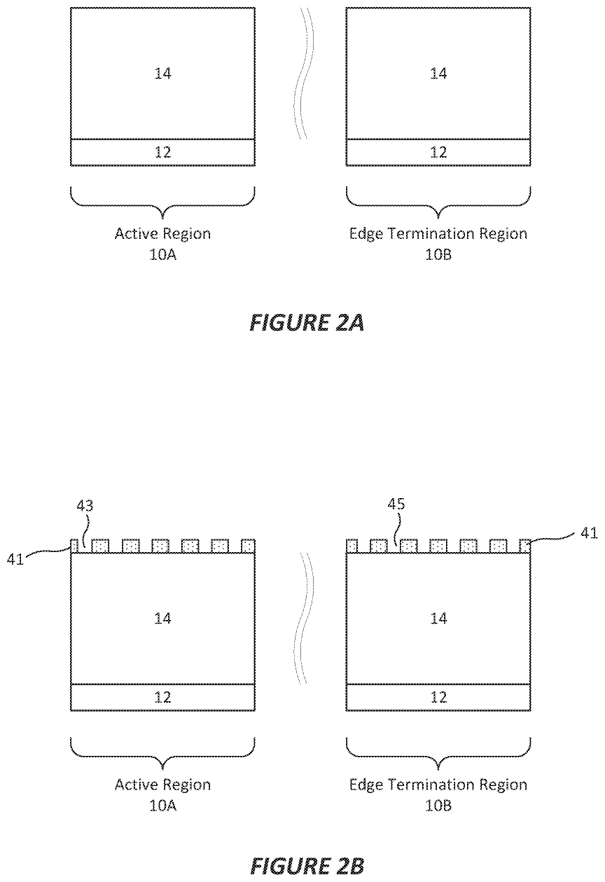

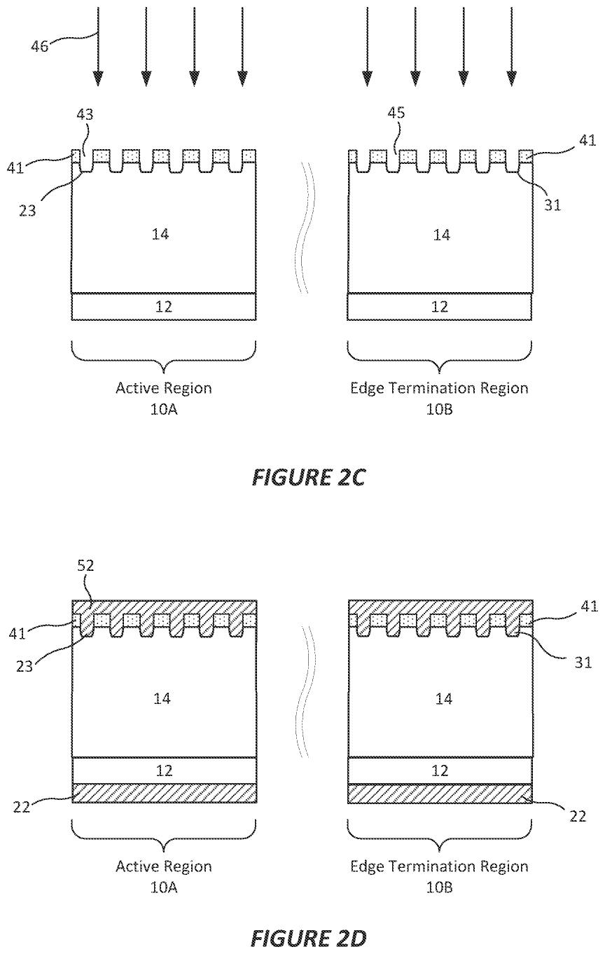

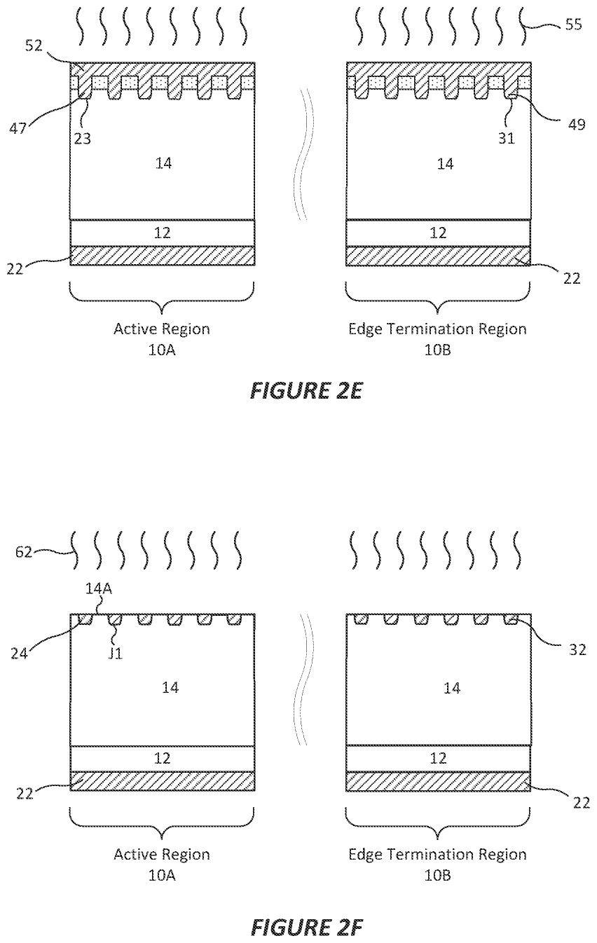

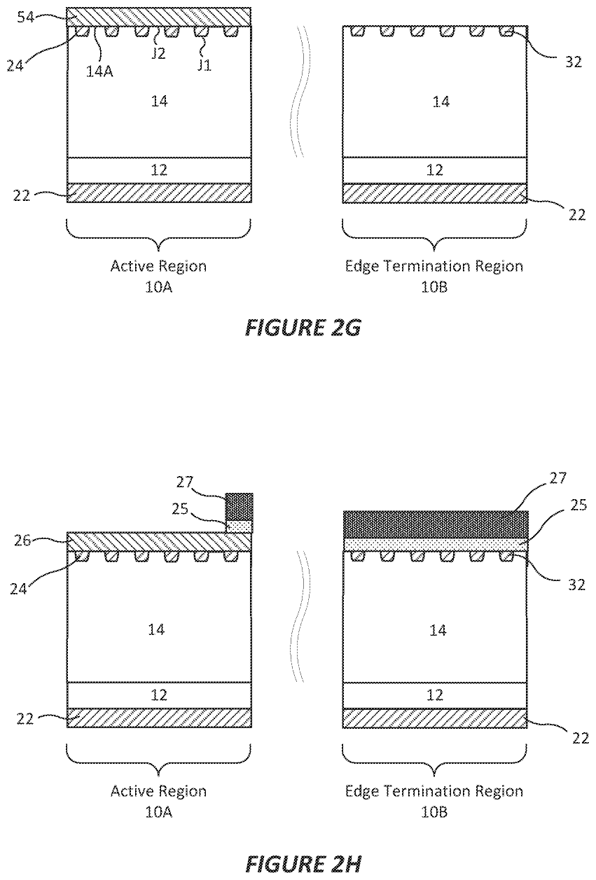

FIGS. 2A to 2H illustrate operations for forming a Schottky diode in accordance with some embodiments.

Referring to FIG. 2A, a silicon carbide substrate 12 is provided. The silicon carbide substrate 12 may have a 2H, 4H, 6H or 3C polytype, and may have an off-angle orientation of about 0 to 5 degrees. A silicon carbide epitaxial layer 14 is formed on the substrate 12. The substrate 12 and epitaxial layer 14 are divided into an active region 10A and an edge termination region 10B, which may surround the active region 10A.

Referring to FIG. 2B, an oxide mask 41 is formed on the epitaxial layer 14. The mask 41 is patterned to form openings 43 in the active region 10A and openings 45 in the termination region 10B.

Referring to FIG. 2C, an anisotropic etch process 46, such as a reactive ion etch process, is performed to form trenches 23 in the epitaxial layer 14 in the active region 10A and trenches 31 in the epitaxial layer 14 in the termination region 10B.

Referring to FIG. 2D, a metal layer 52 is deposited over the mask 41 and in the trenches 23, 31. A backside metal layer 22 may also deposited onto the bottom of the substrate 12. The metal layer 52 and the backside metal layer 22 may each include a metal such as nickel that forms a silicide. In some embodiments, the metal may include tantalum, titanium and/or tungsten.

Referring to FIG. 2E, a silicidation anneal 55 is performed by using a rapid thermal anneal to heat the structure to a temperature of about 600° C. to about 700° C., and in some cases at least about 650° C., to form metal silicide regions 47 in the trenches 23 and metal silicide regions 49 in the trenches 31. Portions of the backside metal layer 22 in contact with the substrate 12 may also become silicided. However, upper portions of the metal layer 52 and portions of the metal layer 52 shielded by the mask 41 may not become silicided.

Referring to FIG. 2F, non-silicided portions of the metal layer 52 may be stripped from the epitaxial layer 14 along with the mask 41, leaving metal silicide regions 24 in the active region 10A of the epitaxial layer 14 and metal silicide regions 32 in the termination region 10B of the epitaxial layer 14. A high temperature anneal 62 is then performed on the structure at a temperature of about 850° C. to 900° C., which can cause the metal silicide regions 24 to form a first Schottky junction J1 with the epitaxial layer 14. The anneal 62 can also cause the backside contact 22 to form an ohmic contact with the n-type silicon carbide substrate 12.

Referring to FIG. 2G, a metal layer 64 is formed on the epitaxial layer 14 in the active region 10A. The metal layer 64 may include nickel, titanium, molybdenum, titanium and/or tungsten. The metal layer 54 contacts the epitaxial layer 14 in the gaps 14A between the metal silicide regions 24. The metal layer 54 may form a second Schottky junction J2 to the epitaxial layer 14. The second Schottky junction J2 may have a lower Schottky barrier to the epitaxial layer 14 than the first Schottky junction J1 between the silicide regions 24 and the epitaxial layer 14. In some embodiments, after formation of the metal layer 54, the structure may be annealed at a low temperature (e.g., 250° C. to 500° C.) to cause the metal layer 54 to wet to the upper surface of the epitaxial layer 14.

Referring to FIG. 2H, a silicon nitride passivation layer 25 is formed over the edge termination region 10B and extends onto the Schottky contact 26 in the active region 10A. A protective layer 27 of a material such as polyimide is formed on the silicon nitride passivation layer 25.

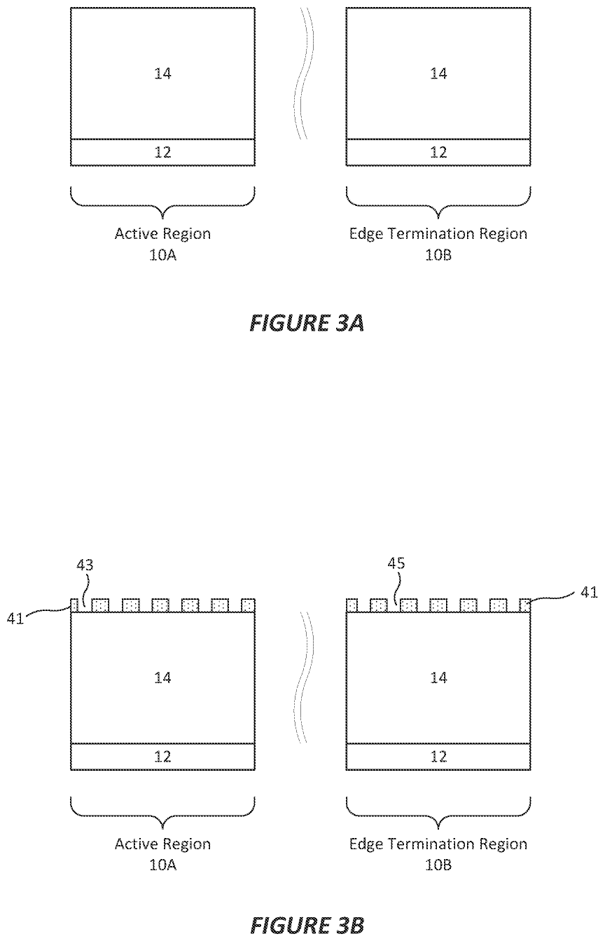

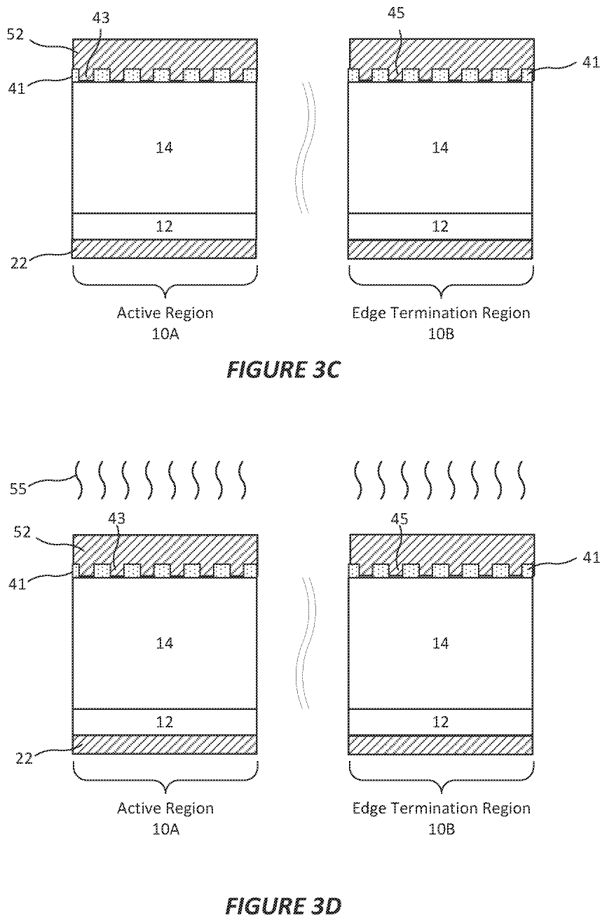

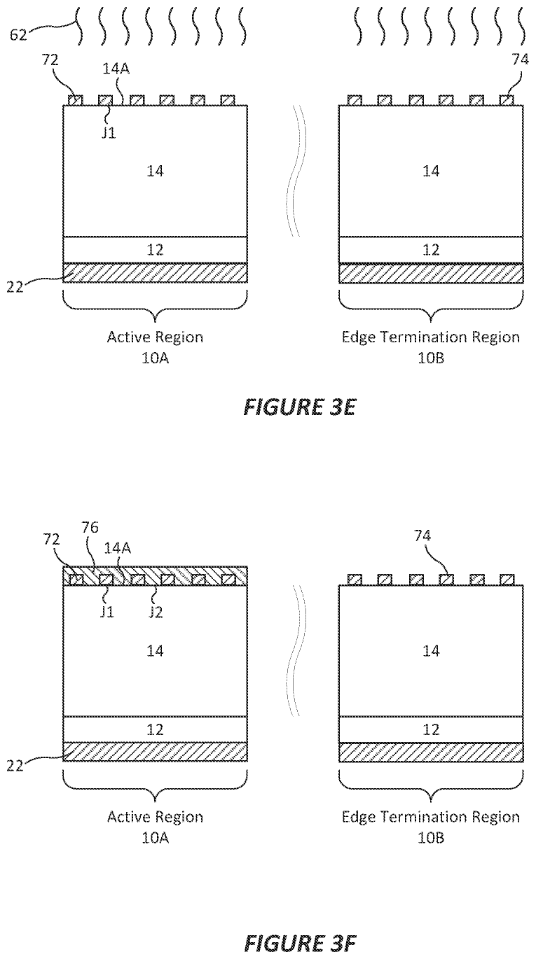

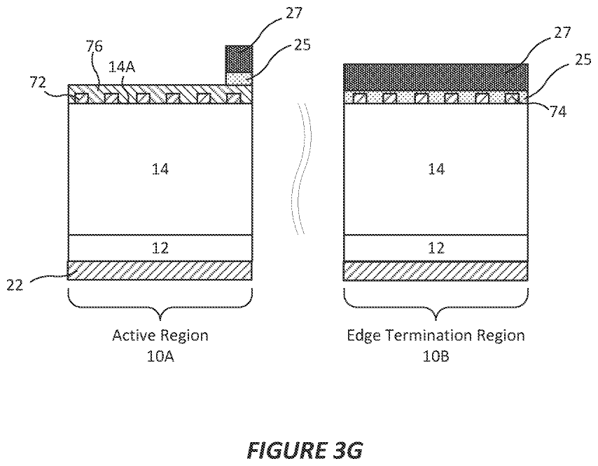

FIGS. 3A to 3F illustrate operations for forming a Schottky diode in accordance with further embodiments. In particular, FIGS. 3A to 3F illustrate the formation of a planar Schottky device structure in accordance with some embodiments that does not include the trenches shown in FIG. 1.

Referring to FIG. 3A, a silicon carbide substrate 12 is provided. The silicon carbide substrate may have a 2H, 4H, 6H or 3C polytype, and may have an off-angle orientation of about 0 to 5 degrees. A silicon carbide epitaxial layer 14 is formed on the substrate 12. The substrate 12 and epitaxial layer 14 are divided into an active region 10A and an edge termination region 10B, which may surround the active region 10A.

Referring to FIG. 3B, an oxide mask 41 is formed on the epitaxial layer 14. The mask 41 is patterned to form openings 43 in the active region 10A and openings 45 in the termination region 10B.

Referring to FIG. 3C, a metal layer 52 is deposited over the mask 41. A backside metal layer 22 is also deposited onto the bottom of the substrate 12. The metal layer 52 and the backside metal layer 22 may each include a metal such as nickel that forms a silicide.

Referring to FIG. 3D, a silicidation anneal 55 is performed by using a rapid thermal anneal to heat the structure to a temperature of at least about 650° C. to form metal silicide regions in regions where the metal layer 52 contacts the epitaxial layer 14 in the openings 43, 45. Portions of the backside metal layer 22 in contact with the substrate 12 may also become silicided. However, upper portions of the metal layer 52 and portions of the metal layer 52 shielded by the mask 41 may not become silicided.

Referring to FIG. 3E, non-silicided portions of the metal layer 52 may be stripped from the epitaxial layer 14 along with the mask 41, leaving metal silicide regions 72 on the epitaxial layer 14 in the active region 10A of the epitaxial layer 14 and metal silicide regions 74 on the epitaxial layer 14 in the termination region 10B of the epitaxial layer 14. A high temperature anneal 62 is then performed on the structure at a temperature of about 850° C. to 900° C., which can cause the metal silicide regions 72 to form a first Schottky junction J1 with the epitaxial layer 14. The anneal 62 can also cause the backside contact 22 to form an ohmic contact with the n-type silicon carbide substrate 12.

Referring to FIG. 3F, a metal layer 76 is formed on the epitaxial layer 14 in the active region 10A. The metal layer 64 may include nickel, titanium, molybdenum and/or tungsten. The metal layer 76 contacts the epitaxial layer 14 in the gaps 14A between the metal silicide regions 24 and forms a second Schottky junction J2 to the epitaxial layer. The second Schottky junction J2 may have a lower Schottky barrier to the epitaxial layer 14 than the first Schottky junction J1 between the silicide regions 74 and the epitaxial layer 14. In some embodiments, after formation of the metal layer 76, the structure may be annealed at a low temperature (e.g., 250° C. to 500° C.) to cause the metal layer 76 to wet to the upper surface of the epitaxial layer 14.

Referring to FIG. 3G, a silicon nitride passivation layer 25 is formed over the edge termination region 10B and extends onto the Schottky contact 26 in the active region 10A. A protective layer 27 of a material such as polyimide is formed on the silicon nitride passivation layer 25.

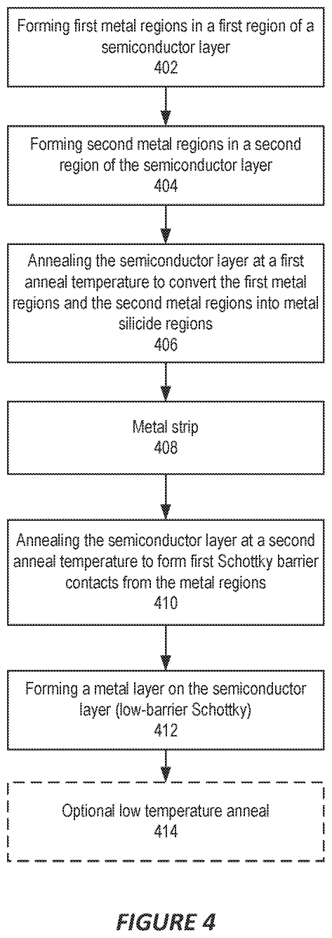

FIG. 4 is a flowchart illustrating operations according to some embodiments. Referring to FIG. 4, a method of manufacturing a semiconductor device includes forming first metal regions on a semiconductor layer in a first region of the semiconductor layer (block 402). The semiconductor layer comprises silicon and wherein the first metal regions comprise a first metal. The method further includes forming second metal regions on the semiconductor layer in a second region of the semiconductor layer (block 404). The second metal regions include the first metal.

The semiconductor layer including the first and second metal regions is annealed (block 406) at a first anneal temperature that is sufficient to convert at least portions of the first metal regions and the second metal regions into first metal silicide regions and second metal silicide regions, respectively. The first anneal temperature may be about 650° C. Un-silicided portions of the first and second metal regions are then removed (block 408).

The semiconductor layer including the first and second metal silicide regions is then annealed at a second anneal temperature that is sufficient to cause the first metal silicide regions to form a first Schottky barrier contact to the semiconductor layer (block 410). The second anneal temperature may be about 850° C. to 900° C.

A metal layer is then formed (block 412) on the semiconductor layer in the first region of the semiconductor layer. The metal layer contacts the first metal silicide regions and contacts the semiconductor layer in spaces between the first metal silicide regions. Optionally, the structure may be annealed at a low temperature (e.g., 250° C. to 500° C.) to cause the metal layer to wet to the semiconductor layer (block 414).

The metal layer forms a second Schottky junction to the semiconductor layer in the spaces between the first metal silicide regions. The second Schottky junction has a lower Schottky barrier height to the semiconductor layer than the first Schottky junction.

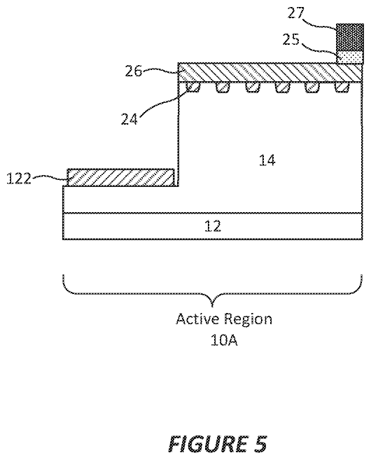

An alternative Schottky diode structure according to some embodiments is illustrated in FIG. 5. As shown therein, in some embodiments, a cathode ohmic contact 122 may be formed to an exposed portion of the epitaxial layer 14 on the front side of the epitaxial layer 14 opposite the substrate 12.

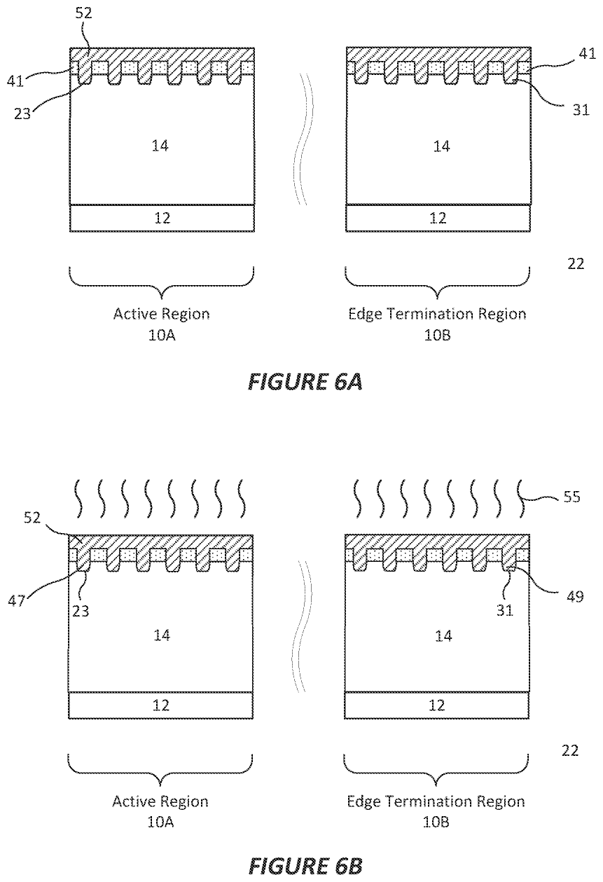

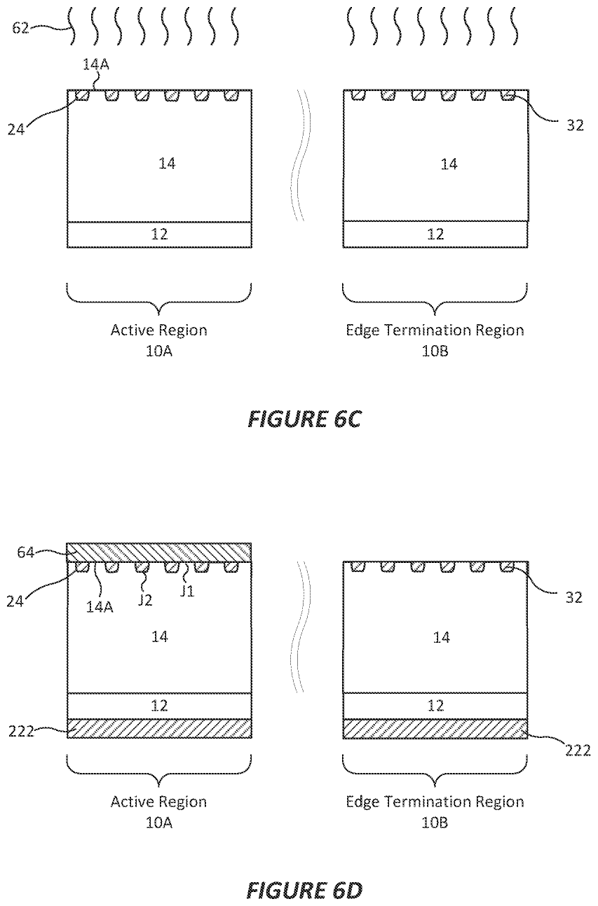

Operations according to further embodiments are illustrated in FIGS. 6A to 6D. As shown in FIG. 6A, the metal layer 52 is formed on the epitaxial layer 14 without also forming a backside metal layer. That is, a backside metal layer may not be formed at the same time as the metal layer 52 is formed on the epitaxial layer 14.

Referring to FIG. 6B, the anneal process 55 may be formed to cause portions of the metal layer 52 to become silicided without the backside metal layer being present.

Referring to FIG. 6C, the anneal process 62 may also be performed to cause the silicided regions 24 to form a Schottky junction with the epitaxial layer 14 without the backside metal being present. Referring to FIG. 6D, after the anneal process 62, a backside metal layer 222 may be formed on the substrate 12.

The substrate 12 may be thinned prior to deposition of the backside metal layer 222. Moreover, the backside metal layer may be laser annealed to form an ohmic contact to the substrate 12. Remaining processing steps are similar to those described above.

Various test structures were fabricated including contacts formed as described above to demonstrate performance/cost tradeoffs at different voltage ratings, and the results are shown in Table 1 below.

TABLE 1
Performance Results

| | Thinning/Substrate | | | | VF | VF | VF | Leakage | |
|---|---|---|---|---|---|---|---|---|---|
| Type | Thickness | VRating | | VF | (barrier) | (drift) | (substrate) | current | |
| Planar | Yes/180 um | 650 | V | 1.26 V | 0.98 V | 0.12 V | 0.16 V | 300 | uA |
| Trench | Yes/180 um | 650 | V | 1.29 V | 0.98 V | 0.15 V | 0.16 V | 70 | uA |
| Trench | Yes/180 um | 1200 | V | 1.38 V | 0.96 V | 0.33 V | 0.09 V | 7 | uA |
| Trench | Yes/180 um | 1700 | V | 1.41 V | 0.92 V | 0.43 V | 0.06 V | 4 | uA |
| Trench | No/360 um | 1700 | V | 1.47 V | 0.92 V | 0.43 V | 0.12 V | 4 | uA |

In particular, Table 1 illustrates results for different device structures (planar or trench) having different voltage ratings. Table 1 illustrates the forward voltage (VF) and leakage current of the devices. Forward voltage is broken down into VF components corresponding to VF in the barrier, the drift layer and the substrate.

As can be seen in Table 1, at higher voltage ratings (e.g., 1700V), part of the VF in the substrate is lower (<10% for 1700V with full thickness substrate). Thus, in high voltage devices, substrate thinning is less important for performance. At 650V voltage rating, more than 13% of VF is in the substrate even with the substrate thinned to 180 um. Thus, it may be desirable to thin the substrate for low voltage devices. For the planar device structure, eliminating the trench etch may improve VF but may increase leakage current.

It will be understood that, although the ordinal terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Furthermore, relative terms, such as “lower” or “bottom” and “upper” or “top,” may be used herein to describe the relationship of one element to another as illustrated in the drawings. It is understood that relative terms are intended to encompass different orientations of the device in addition to the orientation depicted in the drawings. For example, if the device in one of the drawings is turned over, features described as being on the “lower” side of an element would then be oriented on “upper” side of that element. The exemplary term “lower” can therefore describe both lower and upper orientations, depending of the particular orientation of the device. Similarly, if the device in one of the drawings is turned over, elements described as “below” or “beneath” other elements would then be oriented above those other elements. The exemplary terms “below” or “beneath” can therefore describe both an orientation of above and below.

The terminology used in the description of the disclosure herein is for the purpose of describing particular embodiments only and is not intended to be limiting of the disclosure. As used in the description of the disclosure and the appended claims, the singular forms “an” and “the” are intended to include the plural forms as well, unless the context clearly indicates otherwise. It is also understood that the term “and/or” as used herein refers to and encompasses any and all possible combinations of one or more of the associated listed items. It will be further understood that the terms “comprises” and “comprising,” when used in this specification, specify the presence of stated steps, operations, features, elements, and/or components, but do not preclude the presence or addition of one or more other steps, operations, features, elements, components, and/or groups thereof.

Embodiments of the disclosure are described herein with reference to cross-section illustrations that are schematic illustrations of idealized embodiments of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. The regions illustrated in the drawings are schematic in nature, and their shapes are not intended to illustrate the actual shape of a region of a device and are not intended to limit the scope of the disclosure unless explicitly stated otherwise. Further, lines that appear straight, horizontal, or vertical in the below drawings for schematic reasons will often be sloped, curved, non-horizontal, or non-vertical. Further, while the thicknesses of elements are meant to be schematic in nature.

Unless otherwise defined, all terms used in disclosing embodiments of the disclosure, including technical and scientific terms, have the same meaning as commonly understood by one of ordinary skill in the pertinent art and are not necessarily limited to the specific definitions known at the time of the present disclosure. Accordingly, these terms can include equivalent terms that are created after such time. It is further understood that terms, such as those defined in commonly used dictionaries, should be interpreted as having a meaning that is consistent with their meaning in the present specification and in the context of the relevant art.

Although embodiments of the inventive concepts have been described in considerable detail with reference to certain configurations thereof, other versions are possible. Accordingly, the spirit and scope of the invention should not be limited to the specific embodiments described above.

What is claimed is:

1. A method of manufacturing a semiconductor device, comprising:
forming first metal regions on a semiconductor layer in a first region of the semiconductor layer, wherein the first metal regions comprise a first metal;
forming second metal regions on the semiconductor layer in a second region of the semiconductor layer, wherein the second metal regions comprise the first metal;
annealing the semiconductor layer including the first and second metal regions at a first anneal temperature;
annealing the semiconductor layer at a second anneal temperature that is different from the first anneal temperature; and
forming a first metal layer on the semiconductor layer in the first region of the semiconductor layer, wherein the first metal layer comprises a second metal that is different from the first metal, and wherein the first metal layer contacts the first metal regions and contacts the semiconductor layer in spaces between the first metal regions.

2. The method of claim 1, wherein the semiconductor layer comprises silicon carbide.

3. The method of claim 1, wherein the first metal regions and the second metal regions are formed at the same time.

4. The method of claim 1, the first anneal temperature is sufficient to convert at least portions of the first metal regions and the second metal regions into first metal silicide regions and second metal silicide regions, respectively.

5. The method of claim 4, wherein the second anneal temperature is sufficient to cause the first metal silicide regions to form a Schottky barrier junction to the semiconductor layer.

6. The method of claim 4, further comprising removing un-silicided portions of the first metal regions and the second metal regions after annealing the semiconductor layer at the first anneal temperature to form the first and second metal silicide regions.

7. The method of claim 4, wherein the first metal silicide regions form a first Schottky barrier junction to the semiconductor layer and the first metal layer forms a second Schottky barrier junction to the semiconductor layer, wherein the first Schottky barrier junction has a first Schottky barrier height and the second Schottky barrier junction has a second Schottky barrier height that is lower than the first Schottky barrier height.

8. The method of claim 7, wherein the first Schottky barrier height is at least about 0.5 eV greater than the second Schottky barrier height.

9. The method of claim 7, wherein the first Schottky barrier height is about 1.6 eV or greater and the second Schottky barrier height is about 1.2 eV or lower.

10. The method of claim 1, wherein the first region of the semiconductor layer corresponds to an active region of the semiconductor device and the second region of the semiconductor layer corresponds to an edge termination region of the semiconductor device.

11. The method of claim 1, wherein the first anneal temperature is from about 600° C. to about 700° C. and the second anneal temperature is from about 850° C. to about 900° C.

12. The method of claim 1, wherein the semiconductor layer comprises a substrate and an epitaxial layer on the substrate, the method further comprising:
forming a second metal layer on a backside of the substrate opposite the epitaxial layer, wherein the second metal layer comprises the first metal.

13. The method of claim 12, wherein the first metal regions and the second metal layer are formed at the same time.

14. The method of claim 12, wherein annealing the semiconductor layer at the second anneal temperature comprises annealing the semiconductor layer including the first metal regions and the second metal layer at the second anneal temperature.

15. The method of claim 13, wherein the second anneal temperature is sufficient for the first metal regions to form a Schottky barrier contact to the semiconductor layer and for the second metal layer to form an ohmic contact to the doped region of the semiconductor layer.

16. The method of claim 15, wherein the second anneal temperature is from about 850° C. to about 900° C.

17. The method of claim 13, wherein the semiconductor layer comprises an epitaxial semiconductor layer on a front surface of a semiconductor substrate, and wherein the second metal layer is formed on the epitaxial semiconductor layer.

18. The method of claim 1, wherein the first metal comprises nickel, titanium, molybdenum and/or tungsten, and wherein second metal comprises titanium or titanium nitride.

19. The method of claim 1, wherein the semiconductor layer comprises silicon carbide.

20. The method of claim 1, further comprising:
forming a first plurality of trenches in the first region of the semiconductor layer, wherein the first metal regions are formed in the first plurality of trenches.

21. The method of claim 20, further comprising:
forming a second plurality of trenches in the second region of the semiconductor layer, wherein the second metal regions are formed in the second plurality of trenches.

22. The method of claim 1, further comprising:
forming a plurality of trenches in the second region of the semiconductor layer, wherein the second metal regions are formed in the plurality of trenches.

23. The method of claim 1, wherein forming the first metal regions and the second metal regions on the semiconductor layer comprises:
forming a mask on the semiconductor layer;
forming openings in the mask in the first region and the second region of the semiconductor layer to expose respective areas of the semiconductor layer;
depositing a preliminary layer of the first metal on the semiconductor layer, wherein the preliminary layer of the first metal contacts the semiconductor layer in the exposed areas of the semiconductor layer, and wherein annealing the semiconductor layer causes portions of the preliminary layer of the first metal contacting the semiconductor layer to become silicided; and
after annealing the semiconductor layer, stripping the mask and un-silicided portions of the preliminary layer of the first metal from the semiconductor layer.

24. A semiconductor device, comprising:
a semiconductor layer comprising an active region and an edge termination region;
first metal regions on the semiconductor layer in the active region of the semiconductor layer, wherein the first metal regions comprise a first metal;
second metal regions on the semiconductor layer in the edge termination region of the semiconductor layer, wherein the second metal regions comprise the first metal; and
a first metal layer on the semiconductor layer in the active region of the semiconductor layer, wherein the first metal layer comprises a second metal, and wherein the first metal layer contacts the first metal regions and contacts the semiconductor layer in spaces between the first metal regions.

25. The semiconductor device of claim 24, wherein the semiconductor layer comprises silicon carbide.

26. The semiconductor device of claim 24, wherein the first metal regions comprise first metal silicide regions and the second metal regions comprise second metal silicide regions.

27. The semiconductor device of claim 26, wherein the first metal silicide regions form a first Schottky barrier junction to the semiconductor layer in the first region of the semiconductor layer, wherein the first Schottky barrier junction has a first Schottky barrier height; and
wherein the first metal layer forms a second Schottky barrier junction to the semiconductor layer, the second Schottky barrier junction having a second Schottky barrier height that is lower than the first Schottky barrier height.

28. The semiconductor device of claim 27, wherein the first Schottky barrier height is at least about 0.5 eV greater than the second Schottky barrier height.

29. The semiconductor device of claim 27, wherein the first Schottky barrier height is about 1.6 eV or greater and the second Schottky barrier height is about 1.2 eV or lower.

30. The semiconductor device of claim 24, wherein the semiconductor layer comprises an epitaxial layer on a substrate, the semiconductor device further comprising:
a second metal layer on a back side of the substrate opposite the epitaxial layer, wherein the second metal layer comprises the first metal.

31. The semiconductor device of claim 30, wherein the second metal layer forms an ohmic contact to the substrate.

32. The semiconductor device of claim 24, wherein the first metal comprises nickel, titanium, molybdenum and/or tungsten, and wherein second metal comprises titanium or titanium nitride.

33. The semiconductor device of claim 24, wherein the semiconductor layer comprises silicon carbide.

34. The semiconductor device of claim 24, further comprising:
a first plurality of trenches in the active region of the semiconductor layer, wherein the first metal regions are in the first plurality of trenches.

35. The semiconductor device of claim 34, further comprising:
a second plurality of trenches in the edge termination region of the semiconductor layer, wherein the second metal regions are in the second plurality of trenches.

36. The semiconductor device of claim 24, further comprising:
a plurality of trenches in the edge termination region of the semiconductor layer, wherein the second metal regions are in the plurality of trenches.
